(19) United States
(12) Patent Application Publication
(10) Pub. No.: US 2007/0024183 A1
(43) Pub. Date: Feb. 1, 2007

(54) Full-color organic electroluminescence panel with high resolution

(75) Inventors: Jiin-Jou Lih, Taichung City (TW); Ching-Ian Chao, Jhudong Township (TW); Li-Wei Shih, Minsyong Township (TW); Kuan-Long Wu, Mituo Township (TW); Che-Jen Chen, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/338,311

(22) Filed: Jan. 24, 2006

(30) Foreign Application Priority Data
Jul. 29, 2005 (TW) 94125928

(51) Int. Cl. H01J 1/62; H01J 63/04

(52) U.S. Cl. 313/504; 313/506

(57) ABSTRACT

A full-color organic electroluminescence panel with high resolution comprises a substrate and a plurality of sub-pixel units formed on the substrate. Each sub-pixel unit includes four sub-pixel elements emitting light with the same color. Also, the light color emitted from each sub-pixel unit is different from the light color emitted from the adjacent sub-pixel unit.

This application claims the benefit of Taiwan application Serial No. 094125928, filed Jul. 29, 2005, the subject matter of which is incorporated herein by reference.

### BACKGROUND OF THE INVENTION

1. Field of the Invention

The invention relates in general to a full-color organic electroluminescent panel, and more particularly to the full-color organic electroluminescent panel with high resolution.

2. Description of the Related Art

Use of organic electroluminescence device in the flat panel displays possesses several competitive advantages, such as self illumination, high brightness, wide viewing angle, vivid contrast, quick response, broad range of operating temperature, high luminous efficiency and uncomplicated process of fabrication. Thus, the organic electroluminescence device represents a promising technology for display applications and has receives the worldwide attention in the recent years.

The typical structure of organic electroluminescence device is mainly constructed by interposing organic layers between an anode and a cathode. A hole transport layer (HTL) is interposed between the anode and the organic light emitting layer. An electron transport layer (ETL) is interposed between the cathode and the organic light emitting layer. Also, a hole injection layer (HIL) could be interposed between the anode and the hole transport layer. The organic light emitting layer can be divided into tow groups according to the materials in use. One group is a molecule-based light emitting diode, substantially comprising the dyestuffs or pigments, and so called as “OLED” (i.e. organic light emitting diode) or “OEL” (i.e. organic electroluminescence). The other group is a polymer-based light emitting diode, so called as “PLED” (i.e. polymer light emitting diode) or “LEP” (i.e. light emitting polymer). Also, the organic light emitting layer includes a R (red) emissive material, a G (green) emissive material or a B (blue) emissive material emissive material, according to the colors emitting from the materials.

Generally, the full-color organic electroluminescent panel includes a plurality of sub-pixel elements RGB arranged in a particular pattern. A pixel at least includes a sub-pixel element R, a sub-pixel elements G and a sub-pixel elements B. In the commercial market, the arrangement of the sub-pixel elements RGB of the full-color organic electroluminescent panel adopts the color element design of the liquid crystal display (LCD), such as a stripe arrangement, a mosaic arrangement and a delta (i.e. triangle) arrangement. Further, the stripe arrangement is the most common design used in the full-color organic electroluminescent panel.

FIG. 1A is a top view illustrating a conventional full-color organic electroluminescent panel adopting a stripe arrangement. FIG. 1B is a top view illustrating a shadow mask used for forming the sub-pixel elements RGB of FIG. 1A. As shown in FIG. 1A and FIG. 1B, the sub-pixel elements RGB of FIG. 1A are discretely formed by the evaporation method using the shadow mask 1. The pattern (consisting of the openings 11) of the shadow mask 1 is determined according to the positions of the sub-pixel elements emitting the same light color. First, a light emitting layer for emitting light color R is formed by evaporating only a light color R luminescent material. Then, the shadow mask 1 is shifted by a distance to evaporate only a light color G luminescent material and form the light emitting layer for emitting light color G. Finally, the shadow mask 1 is shifted again by a distance, and a light emitting layer for emitting light color B is formed by evaporating only a light color B luminescent material. Also, three shadow masks can be individually used for completing the formation of the sub-pixel elements RGB. In the procedures of evaporation, the size of each opening 11 is corresponding to the evaporating area of each sub-pixel element. Thus, resolution of organic electroluminescent panel depends on the size of the opening 11. If it is desired to have a rise in resolution, not only the areas of the sub-pixel elements have to be reduced but also the arrangement of the sub-pixel elements should be denser. However, the openings 11 of the shadow mask 1 are usually formed by etching, so that the size of the opening 11 is confined due to the limitation of etching technique. Typically, the limitation of diameter φ of the opening 11 is in a range of 40 μm to 50 μm, and the adjacent openings are spaced a distance d at least of 40 μm apart. Accordingly, resolution and production yield of the conventional full-color organic electroluminescent panel are subject to the ability of fabricating the shadow mask 11. Most of the conventional full-color organic electroluminescent panels have the resolution of 120 ppi (pixel per inch) to 150 ppi, and less than 180 ppi in general.

### SUMMARY OF THE INVENTION

It is therefore an object of the present invention to provide a full-color organic electroluminescent panel with high resolution. The resolution is effectively increased using the present etching technique for making the pattern of the shadow mask. Also, the misalignment of the shadow mask can be avoided during RGB evaporating procedures, and the production yield of the full-color organic electroluminescent panel is increased consequently.

The present invention achieves the objects by providing a full-color organic electroluminescent panel, comprising a substrate, and a plurality of sub-pixel units formed on the substrate. Each sub-pixel unit includes four sub-pixel elements emitting the same light color, and the light color emitted from each sub-pixel unit is different from the light color emitted from the adjacent sub-pixel unit.

Other objects, features, and advantages of the present invention will become apparent from the following detailed description of the preferred but non-limiting embodiment. The following description is made with reference to the accompanying drawings.

### BRIEF DESCRIPTION OF THE DRAWINGS

FIG. 1A (related art) is a top view illustrating a conventional full-color organic electroluminescent panel adopting a stripe arrangement.

FIG. 1B (related art) is a top view illustrating a shadow mask used for forming the sub-pixel elements RGB of FIG. 1A.

FIG. 2A is a top view illustrating the sub-pixel elements RGB of the full-color organic electroluminescent panel according to the first embodiment of the present invention.

FIG. 2B is a top view illustrating a shadow mask used for forming the sub-pixel units of FIG. 2A.

FIG. 3A is a top view illustrating the sub-pixel elements RGB of the full-color organic electroluminescent panel according to the second embodiment of the present invention.

FIG. 3B is a top view illustrating one of the shadow masks used for forming the sub-pixel units of FIG. 3A.

FIG. 4 is a top view illustrating a combination of the shadow masks used for forming the sub-pixel units of FIG. 3A.

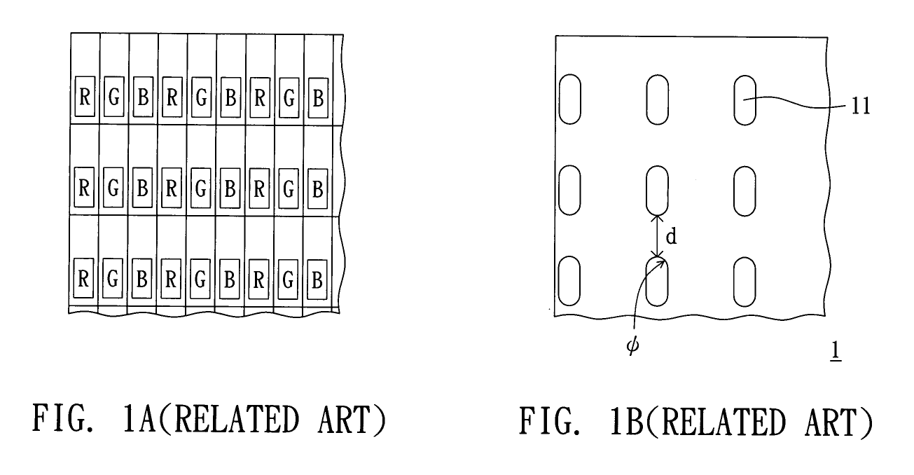

### DETAILED DESCRIPTION OF THE INVENTION

In the present invention, a full-color organic electroluminescent panel with higher resolution is provided, by using a shadow mask fabricated according to the etching technique nowadays. Also, the misalignment of the shadow mask can be avoided during RGB evaporating procedures, and the production yield of the full-color organic electroluminescent panel of the present invention is increased, consequently.

The first and second preferred embodiments disclosed herein are used for illustrating the present invention, but not for limiting the scope of the present invention. Additionally, the drawings used for illustrating the embodiments of the present invention only show the major characteristic parts in order to avoid obscuring the present invention. Accordingly, the specification and the drawings are to be regard as an illustrative sense rather than a restrictive sense.

### First Embodiment

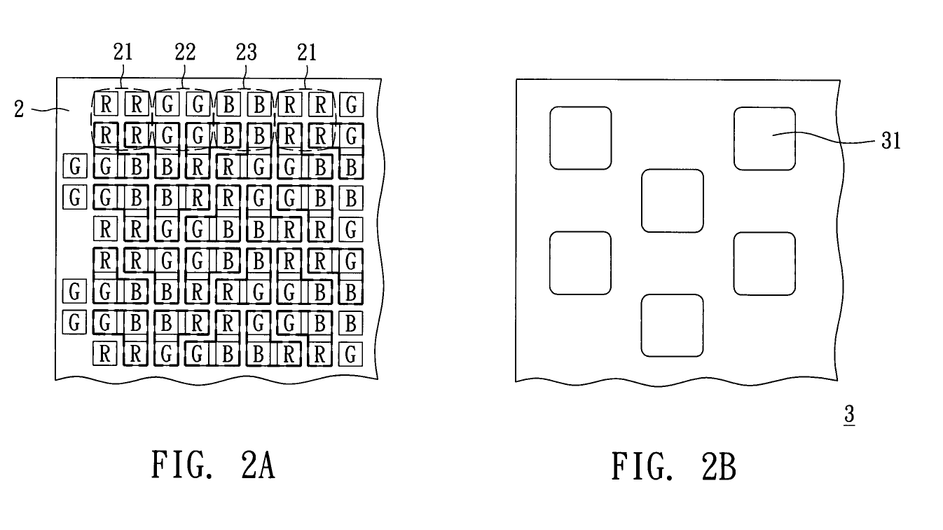

FIG. 2A is a top view illustrating the sub-pixel elements RGB of the full-color organic electroluminescent panel according to the first embodiment of the present invention. FIG. 2B is a top view illustrating a shadow mask used for forming the sub-pixel units of FIG. 2A. In the first embodiment, each pixel area (circled by the black dotted bold lines) includes three sub-pixel elements emitting light with different colors.

Also, several sub-pixel units are formed on a substrate 2, and each sub-pixel unit includes four sub-pixel elements emitting light with the same color. The light color emitted from each sub-pixel unit is different from the light color emitted from the adjacent sub-pixel unit. As shown in FIG. 2A, there are several sub-pixel units R 21, sub-pixel units G 22 and sub-pixel units B 23 arranged on the substrate 2. Each sub-pixel unit R 21 includes four sub-pixel elements R for emitting red light. Similarly, each sub-pixel unit G 22 includes four sub-pixel elements G for emitting green light, and each sub-pixel unit B 23 includes four sub-pixel elements B for emitting blue light. Also, either the sub-pixel unit G 22 or the sub-pixel unit B 23 is adjacent to the sub-pixel unit R 21.

The pattern of the shadow mask 3 of FIG. 2B, including the size and positions of the openings 31, is determined according to the positions of the sub-pixel units emitting the same light color. Practically, a light emitting layer for emitting light color R can be formed by evaporating only a color R luminescent material first. Then, the shadow mask 3 is shifted by a distance to evaporate only a color G luminescent material and form the light emitting layer for emitting light color G. Finally, the shadow mask 3 is shifted again by a distance, and a light emitting layer for emitting light color B is formed by evaporating only a color B luminescent material. Also, three shadow masks 3 can be individually used for completing the formation of the sub-pixel elements RGB. However, any evaporation procedures are possibly used for forming the sub-pixel elements RGB, depending on the needs of the applications.

Since each sub-pixel unit includes four sub-pixel elements, the size of an opening 31 in the embodiment could be about four times larger than the size of the opening in the conventional shadow mask. It is known that the smaller the opening of the shadow mask, the higher the resolution of organic electroluminescent panel. Using the present etching technique, it is easy to reduce the size of the opening 31 for raising the resolution of organic electroluminescent panel. Also, the misalignment of the shadow mask can be avoided during RGB evaporating procedures, and the production yield of the full-color organic electroluminescent panel is increased consequently.

### Second Embodiment

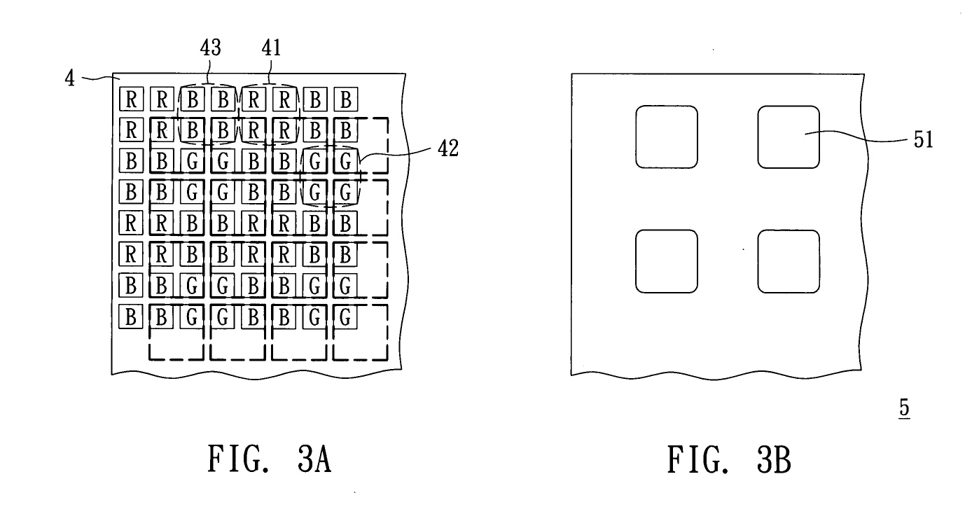

FIG. 3A is a top view illustrating the sub-pixel elements RGB of the full-color organic electroluminescent panel according to the second embodiment of the present invention. FIG. 3B is a top view illustrating one of the shadow masks used for forming the sub-pixel units of FIG. 3A. In the second embodiment, each pixel area (circled by the black dotted bold lines) includes four sub-pixel elements—a sub-pixel element R, a sub-pixel element G and two sub-pixel elements B.

In the second embodiment, several sub-pixel units are also formed on a substrate 4, and each sub-pixel unit includes four sub-pixel elements emitting light with the same color. The light color emitted from each sub-pixel unit is different from the light color emitted from the adjacent sub-pixel unit. As shown in FIG. 3A, there are several sub-pixel units R 41, sub-pixel units G 42 and sub-pixel units B 43 arranged on the substrate 4. Each sub-pixel unit R 41 includes four sub-pixel elements R for emitting red light. Similarly, each sub-pixel unit G 42 includes four sub-pixel elements G for emitting green light, and each sub-pixel unit B 43 includes four sub-pixel elements B for emitting blue light. Also, either the sub-pixel unit G 42 or the sub-pixel unit B 43 is adjacent to the sub-pixel unit R 41. Each pixel area (circled by the black dotted bold lines) includes four sub-pixel elements.

The pattern of the shadow mask 5 of FIG. 3B, including the size and positions of the openings 51, is determined according to the positions of the sub-pixel units emitting the same light color. Practically, a light emitting layer for emitting light color R can be formed by evaporating only a color R luminescent material first. Then, the shadow mask 5 is shifted by a distance to evaporate only a color G luminescent material and form the light emitting layer for emitting light color G. Finally, the shadow mask 5 is shifted again by a distance, and a light emitting layer for emitting light color B is formed by evaporating only a color B luminescent material. For this case, color B luminescent material has to be deposited twice. Also, three shadow masks 5 can be individually used for completing the formation of the sub-pixel elements RGB, depending on the needs of the practical application.

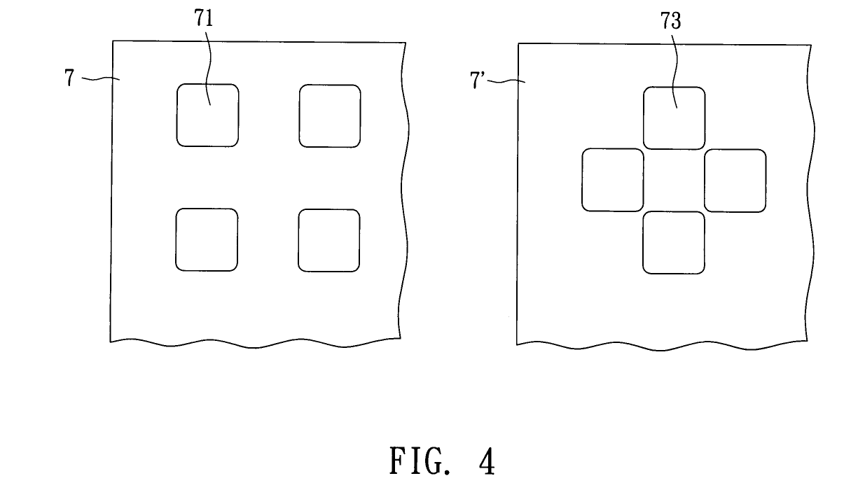

Furthermore, the other shadow mask or a combination of shadow masks can be used for forming the sub-pixel elements RGB arranged in FIG. 3A. For example, the shadow masks 7 and 7′ as shown in FIG. 4 can be adopted for forming the sub-pixel units in the second embodiment. The openings 71 of the shadow mask 7 are sized and positioned in accordance with the sub-pixel unit R 41 and the sub-pixel unit G 42. The openings 73 of the shadow mask 7′ are sized and positioned in accordance with the sub-pixel unit B 43. In this case, color B luminescent material can be deposited just one time. In the present invention, any shadow mask or the combination thereof, having the adequate pattern(s) for forming the sub-pixel elements RGB arrangement depicted in FIG. 3A, is applicable and not limited in the present invention.

The smaller the opening of the shadow mask, the higher the resolution of organic electroluminescent panel. The size of an opening 51, 71 or 73 is about four times larger than the size of each opening in the conventional shadow mask since each sub-pixel unit of the second embodiment includes four sub-pixel elements. Accordingly, it is easy to reduce the size of the openings 51, 71 and 73 for raising the resolution of organic electroluminescent panel using the present etching technique. Also, the misalignment of the shadow mask can be avoided during RGB evaporating procedures of the present invention, and the production yield of the full-color organic electroluminescent panel is increased consequently.

It is, of course, understood that four sub-pixel elements in a pixel are can be optionally selected, and not limited by the arrangement of FIG. 3A. For example, each pixel area may include one sub-pixel element R, two sub-pixel element G and one sub-pixel elements B, or may include two sub-pixel element R, one sub-pixel element G and one sub-pixel elements B.

Besides, the sub-pixel elements of the full-color organic electroluminescent panel in the embodiments could be driven by a passive matrix method or an active matrix method.

Also, the light emitting layer of the full-color organic electroluminescent panel in the embodiments may contain materials forming molecule-based light emitting diodes substantially comprising the dyestuffs or pigments (so called as “OLED”—organic light emitting diode), or materials forming polymer-based light emitting diodes (so called as “PLED”—polymer light emitting diode). In PLED system, ink-jet printing or screen printing will replace shadow mask process for RGB patterning. The materials used in the light emitting layer are not limited herein.

Also, the full-color organic electroluminescent panel in the embodiments could be the top-emission type or the bottom-emission type. The sub-pixel elements of the full-color organic electroluminescent panel in the embodiments could be designed as the normal structure or inverted structure, depending on the practical requirements.

According to the aforementioned description, since a sub-pixel unit consisting of four sub-pixel elements emitting the same light color can be formed by a larger opening of the shadow mask, the resolution of organic electroluminescent panel is effectively increased. Also, the misalignment of the shadow mask can be avoided during RGB evaporating procedures of the present invention, and the production yield of the full-color organic electroluminescent panel is increased consequently. By applying the sub-pixel unit design of the present invention, the full-color organic electroluminescent panels having the resolution of 200 ppi (pixel per inch), even 270 ppi, can be successfully produced.

While the present invention has been described by way of example and in terms of the preferred embodiment, it is to be understood that the present invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A full-color organic electroluminescent panel, comprising:
a substrate; and
a plurality of sub-pixel units formed on the substrate, each sub-pixel unit including four sub-pixel elements emitting the same light color, and a light color emitted from each sub-pixel unit different from a light color emitted from the adjacent sub-pixel unit.

2. The panel according to claim 1, wherein the sub-pixel units comprises a plurality of sub-pixel elements red (R), a plurality of sub-pixel elements green (G) and a plurality of sub-pixel elements blue (B).

3. The panel according to claim 2, wherein each sub-pixel unit R comprises four sub-pixel elements R, each sub-pixel unit G comprises four sub-pixel elements G, and each sub-pixel unit B comprises four sub-pixel elements B.

4. The panel according to claim 1, wherein the sub-pixel units compose a plurality of pixel areas.

5. The panel according to claim 4, wherein each pixel area comprises three sub-pixel elements emitting different light colors.

6. The panel according to claim 5, wherein each pixel area comprises a sub-pixel element R, a sub-pixel element G and a sub-pixel element B.

7. The panel according to claim 4, wherein each pixel area comprises four sub-pixel elements.

8. The panel according to claim 7, wherein each pixel area comprises one sub-pixel element R, one sub-pixel element G and two sub-pixel elements B.

9. The panel according to claim 7, wherein each pixel area comprises one sub-pixel element R, two sub-pixel elements G and one sub-pixel element B.

10. The panel according to claim 7, wherein each pixel area comprises two sub-pixel elements R, one sub-pixel element G and one sub-pixel element B.

11. The panel according to claim 1, wherein the sub-pixel elements are driven by an active matrix method.

12. The panel according to claim 1, wherein the sub-pixel elements are driven by a passive matrix method.

13. The panel according to claim 1, wherein the sub-pixel elements are a plurality of organic light emitting diodes (OLEDs) substantially comprising dyestuffs or pigments.

14. The panel according to claim 1, wherein the sub-pixel elements are a plurality of polymer light emitting diodes (PLEDs).

15. The panel according to claim 1 is a top emission type full-color organic electroluminescent panel.

16. The panel according to claim 1 is a bottom emission type full-color organic electroluminescent panel.

17. The panel according to claim 1, wherein the sub-pixel elements are designed as a normal structure.

18. The panel according to claim 1, wherein the sub-pixel elements are designed as an inverted structure.
